(19) United States
(12) Patent Application Publication
(10) Pub. No.: US 2022/0093436 A1
(43) Pub. Date: Mar. 24, 2022

(54) MOVABLE ELECTRODE FOR PROCESS CHAMBER

(71) Applicant: Applied Materials, Inc., Santa Clara, CA (US)

(72) Inventor: Rick KUSTRA, San Jose, CA (US)

(21) Appl. No.: 17/028,550

(22) Filed: Sep. 22, 2020

(51) Int. Cl. H01L 21/677; H01L 21/67

(52) U.S. Cl. CPC H01L 21/67742; H01L 21/67225

(57) ABSTRACT

A process chamber is provided including a chamber body enclosing an inner volume; a substrate support disposed in the inner volume; an electrode disposed above the substrate support; and an actuator configured to move the electrode in the process chamber to change a distance between the electrode and the substrate support.

### BACKGROUND

### Field

Embodiments of the present disclosure generally relate to equipment and methods utilized in the manufacture of semiconductor devices. More particularly, embodiments of the present disclosure relate to a substrate processing chamber with a movable electrode.

### Description of the Related Art

Integrated circuits have evolved into complex devices that can include millions of transistors, capacitors and resistors on a single chip. The evolution of chip designs continually involves faster circuitry and greater circuit density. The demands for faster circuits with greater circuit densities impose corresponding demands on the materials used to fabricate such integrated circuits. In particular, as the dimensions of integrated circuit components are reduced to the sub-micron scale, there is a trend to use low resistivity conductive materials as well as low dielectric constant insulating materials to obtain suitable electrical performance from such components.

The demands for greater integrated circuit densities also impose demands on the process sequences used in the manufacture of integrated circuit components. For example, in process sequences that use conventional photolithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

As the pattern dimensions are reduced, the thickness of the energy sensitive resist is correspondingly reduced in order to control pattern resolution. Such thin resist layers can be insufficient to mask underlying material layers during the pattern transfer process due to attack by the chemical etchant. An intermediate layer, called a hardmask, is often used between the energy sensitive resist layer and the underlying material layers to facilitate pattern transfer because of greater resistance to the chemical etchant. Hardmask materials having both high etch selectivity and high deposition rates are often utilized. As critical dimensions (CD) decrease, current hardmask materials lack the desired etch selectivity relative to underlying materials (e.g., oxides and nitrides) and are often difficult to deposit. Thus, there is a need for improved hardmask materials along with improved methods and related equipment for processing these improved hardmask materials.

### SUMMARY

Embodiments of the present disclosure generally relate to equipment and methods utilized in the manufacture of semiconductor devices. More particularly, embodiments of the present disclosure relate to a substrate processing chamber, and components thereof, for forming semiconductor devices.

In one embodiment, a process chamber is provided including a chamber body enclosing an inner volume; a substrate support disposed in the inner volume; an electrode disposed above the substrate support; and an actuator configured to move the electrode in the process chamber to change a distance between the electrode and the substrate support.

In another embodiment, a method of performing a process in a process chamber is provided. The method includes providing RF power to a substrate support disposed in an inner volume of a process chamber to initiate a first plasma in the inner volume to perform a process on a substrate disposed on the substrate support, wherein the process chamber includes an electrode disposed above the substrate support and the electrode is located at a first position during the first plasma; moving the electrode vertically from the first position to a second position; and providing RF power to the electrode located in the second position to initiate a second plasma in the inner volume.

In one embodiment, a process chamber is provided including a chamber body enclosing an inner volume; a substrate support disposed in the inner volume; an electrode disposed above the substrate support; an actuator configured to move the electrode in the process chamber to vertically change a distance between the electrode and the substrate support by at least eight inches; and a bellows, wherein the chamber body comprises a lid disposed above the electrode and the bellows is disposed between the electrode and the lid.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic side cross sectional view of a processing chamber in a processing system showing an electrode of the processing chamber in a first position, according to one embodiment.

FIG. 1B is a schematic side cross sectional view of the processing chamber in the processing system from FIG. 1A showing the electrode of the processing chamber in a second position, according to one embodiment.

FIG. 2 is a process flow diagram of a method for an exemplary deposition and clean to be performed by the processing chamber of FIGS. 1A and 1B, according to one embodiment.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION

Embodiments of the present disclosure relate to a substrate processing chamber configured to (1) generate a plasma (e.g., a capacitively coupled plasma) inside the process chamber for performing one or more processes on semiconductor substrates, and/or (2) generate a plasma to clean the interior of the processing chamber. These substrate processes can include plasma enhanced chemical vapor deposition (PECVD) processes (such as depositions of hardmask films, for example amorphous carbon hardmask films), etch processes, as well as other low pressure plasma processes used to manufacture electronic devices on substrates. Examples of processing chambers and/or systems that may be adapted to benefit from exemplary aspects of the disclosure are the PRODUCER® APF™ PECVD and the PIONEER™ PECVD systems commercially available from Applied Materials, Inc., located in Santa Clara, Calif. It is contemplated that other processing chambers and/or processing platforms, including those from other manufacturers, may be adapted to benefit from aspects of the disclosure.

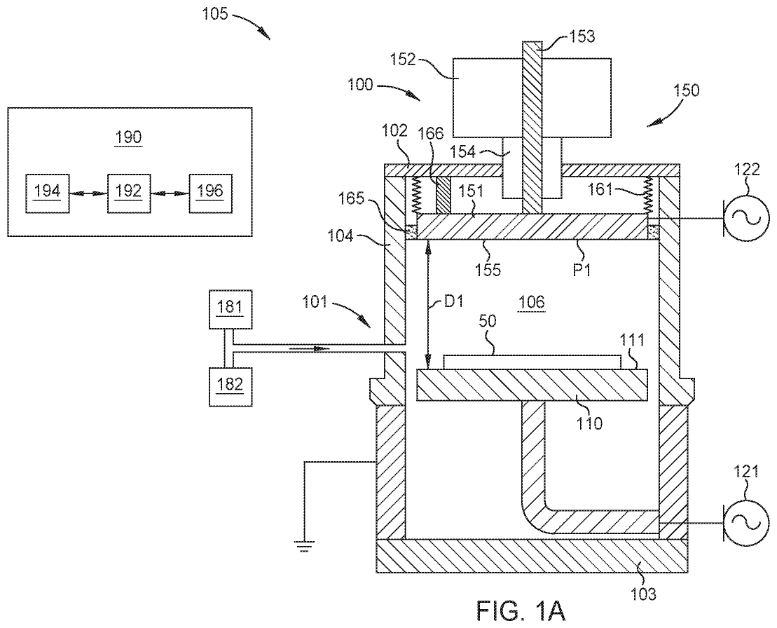

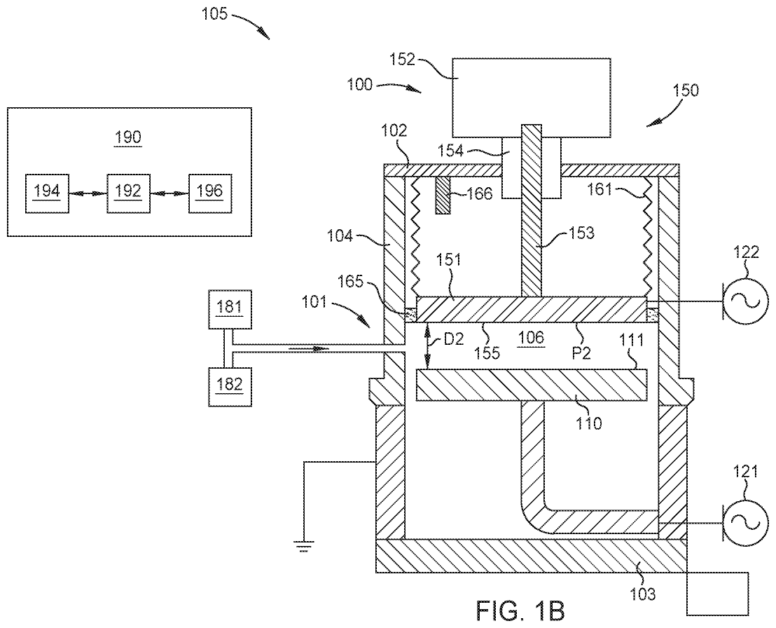

FIG. 1A is a schematic side cross sectional view of a processing chamber 100 in a processing system 105 showing an electrode 151 of the processing chamber 100 in a first position P1, according to one embodiment. In this first position P1 of the electrode 151, a process can be performed on a substrate 50, such as a deposition. FIG. 1B is a schematic side cross sectional view of the processing chamber 100 in the processing system 105 showing the electrode 151 of the processing chamber 100 in a second position P2, according to one embodiment. In this second position P2 of the electrode 151, a cleaning process can be performed for cleaning the interior of the processing chamber 100.

Although the following describes a deposition followed by a cleaning process as two processes that can be performed with the electrode 151 in two different positions, the two processes could just as easily be numerous other types of processes. Some non-limiting examples of two other processes that can be performed include two processes performed on a single substrate (e.g., two depositions or a deposition followed by an etch), two processes performed on different substrates (e.g., a first deposition performed on a first substrate and a second deposition performed on a second substrate), a different process performed on a substrate (e.g., an etch) followed by a clean, or two different cleaning processes. Additionally, the benefits of the disclosure can be expanded to perform three or more different processes by moving the electrode to three or more different positions. Furthermore, the disclosure can also be applied to a single process that can benefit from the electrode being moved during the single process.

The processing chamber 100 includes a chamber body 101 enclosing an inner volume 106. The chamber body 101 includes a lid 102, a bottom 103, and one or more walls 104 disposed between the lid 102 and the bottom 103. The processing system 105 includes process gas sources 181 and cleaning gas sources 182 connected to the processing chamber 100. The process gas sources 181 can provide process gases to the processing chamber 100 during processes performed on a substrate inside the processing chamber 100, such as a deposition. The cleaning gas sources 182 can provide cleaning gases to the processing chamber 100 during cleaning processes performed on the interior of the processing chamber 100. In some embodiments, as shown in FIGS. 1A and 1B, the process gases and cleaning gases can enter the inner volume 106 through a chamber wall 104 between the electrode 151 and a substrate support 110 of the processing chamber 100. In other embodiments (not shown), the process gases and cleaning gases can enter the inner volume through the electrode 151 (e.g., the electrode can function as a showerhead).

The processing chamber 100 further includes a substrate support 110. As shown in FIG. 1A, a substrate 50 can be positioned on the substrate support 110, so that a process, such as a deposition, can be performed on the substrate 50 in the inner volume 106 of the processing chamber 100.

The processing system 105 can further include a first RF power source 121. The substrate support 110 can be connected to the first RF power source 121. In some embodiments, the substrate support 110 includes one or more electrodes (not shown) that are embedded in the substrate support 110 and connected to the first RF power source 121. The first RF power source 121 can be used to create a plasma in the inner volume 106 of the process gases supplied from the process gas sources 181 during a process, such as a deposition being performed on the substrate 50. In some embodiments, a DC bias can be applied to the RF power supplied by the first RF power source 121 to attract process gases, ions, and/or radicals to the substrate 50.

The processing chamber 100 further includes an electrode assembly 150. The electrode assembly 150 includes the electrode 151 (e.g., an anode) and an actuator 152. The electrode 151 is connected to the actuator 152 by a rod 153. The actuator 152 is used to move the electrode 151 during processing and/or between different processes, such as between a deposition process and a clean process. The rod 153 is connected to the actuator 152 through a coupling 154. The coupling 154 can include one or more seals (not shown) to isolate the environment inside the processing chamber 100 from the environment outside the processing chamber 100. In some embodiments, the entire electrode assembly 150 can be positioned inside the processing chamber 100. The actuator 152 can be any type of actuator capable of moving the electrode 151 in a substantially vertical direction. For example, in some embodiments, the actuator 152 can be a linear motor, pneumatic actuator, lead screw, or servo motor.

The electrode 151 can be formed of a conductive material, such as a metallic material, such as aluminum. In some embodiments, which may be combined with other embodiments, a conductive coating can be formed on one or more of the surfaces of the electrode 151, such as a bottom surface 155 of the electrode 151 that faces the substrate support 110. The coating can be formed of a conductive material, such as any silicon-based conductive material. In some embodiments, the coating can be formed of doped material, such as doped silicon or doped silicon carbide. Coatings on the electrode 151, such as silicon carbide, can help reduce the contribution of harmful defects on a substrate caused by the electrode 151. For example, without a coating on the electrode, particles of the metal(s) in the electrode 151 (e.g., aluminum-containing particles) can land on the substrate 50 and cause material defects on the substrate 50. Conversely, in some embodiments, a silicon carbide coating may only lead to carbon-containing particles landing on the substrate 50, which can cause less material defects, especially when a carbon-containing layer is being deposited on the substrate 50 in the processing chamber 100, such as an amorphous carbon hardmask layer. In still other embodiments, which may be combined with other examples herein, a conductive liner formed of, for example, one of the coating materials discussed above can be used. This conductive liner can be mechanically fastened to the bottom surface 155 of the electrode 151. Mechanically fastening a conductive liner can be useful in environments in which delamination of a conductive coating may be a concern, such as high temperature environments (e.g., 60 degrees Celsius or above).

The processing system 105 further includes a second RF power source 122. The second RF power source 122 is connected to the electrode 151. The second RF power source 122 can be used to create a plasma in the inner volume 106 of the cleaning gases supplied from the cleaning gas sources 182 during a cleaning process performed on the interior of the processing chamber 100 when the electrode 151 is in the second position P2 (FIG. 1B). Conversely, when RF power is provided to the substrate support 110 from the first RF power source 121 to create a plasma of process gases when the electrode 151 is in the first position P1 (FIG. 1A), the second RF power source 122 can be de-energized, and the electrode 151 can be electrically connected to ground during this time. For example, when the electrode 151 is in the first position P1 (FIG. 1A), the electrode 151 can be electrically connected to the electrically grounded chamber body 101 through a grounding element 166, such as a coil, spring, or strap, and may be either flexible or rigid. The grounding element 166 can be a conductive material (e.g., aluminum), and the electrode 151 can make electrical contact with the grounding element 166 when the electrode 151 is moved to the first position P1. Furthermore, when the electrode 151 is moved downward from the first position P1, the electrode 151 becomes electrically isolated from the chamber body 101 and electrical ground. For example, when the electrode 151 is at the second position P2 (FIG. 1B), the electrode 151 is electrically isolated from the chamber body 101 and electrical ground.

The processing chamber 100 further includes a bellows 161 and a plasma screen 165. The bellows 161 can be disposed between the electrode 151 and the lid 102 to isolate much of the area between the electrode 151 and the lid 102 from the inner volume 106 below the electrode 151. The bellows 161 is configured to extend (see FIG. 1B) or contract (see FIG. 1A) when the electrode 151 is moved by the actuator 152.

The plasma screen 165 is positioned around the outer edge of the electrode 151, for example completely surrounding the electrode 151, to further assist in isolating the area between the electrode 151 and the lid 102 from the inner volume 106 below the electrode 151. The plasma screen 165 can be configured to move when the electrode 151 is moved by the actuator 152. In some embodiments, the plasma screen 165 can occupy the space between the electrode 151 and the chamber wall(s) 104, so that there is no empty space between the electrode 151 and the chamber walls 104 that is not occupied by the plasma screen 165 or some of other component, such as a liner (not shown). The plasma screen 165 can include a plurality of slots dimensioned to block the plasma from entering the region of the processing chamber 100 above the electrode 151 while permitting the passage of gases. As further described below, the electrode 151 can be electrically grounded along with the chamber body 101 when the substrate support 110 is energized with RF power to generate a plasma, and this electrical grounding of the electrode 151 during this time can help prevent any plasma from being generated above the electrode 151. Thus, the combination of the electrical grounding of the electrode 151 along with the plasma screen 165 can help prevent any plasma from entering the space above the electrode 151.

In the embodiment shown in FIGS. 1A and 1B, the bellows 161 is located at the outer edge of the electrode 151, which can reduce the volume enclosed by the bellows 161, the plasma screen 165, the electrode 151, and the chamber walls 104. This reduced volume can reduce the amount of cleaning performed in this volume. However, in another embodiment, a smaller bellows (not shown) can be used that surrounds the rod 153 at a position closer to the center of the electrode 151 than the bellows 161 shown in FIGS. 1A and 1B. In this other embodiment, the grounding element 166 can also be positioned more closely to the rod 153 to remain inside the smaller-diameter bellows. In such an example, the diameter of the bellows may be about 75 percent or less of the diameter of the electrode 151, for example, about 60 percent or less, such as about 50 percent or less, such as about 40 percent or less, such as about 30 percent or less, such as about 20 percent or less, such as about 10 percent or less, of the diameter of the electrode 151.

The actuator 152 moves the electrode 151 to different positions inside the processing chamber 100 when different processes are being executed by the processing chamber 100. In FIG. 1A, the actuator 152 has moved the electrode 151 to a first position P1, so that a deposition can be performed on the substrate 50. In FIG. 1B, the actuator 152 has moved the electrode 151 to a second position P2, so that a cleaning process can be performed on the interior of the processing chamber 100. The following describes an exemplary deposition and clean process performed by the process chamber 100.

The processing system 105 can further include a controller 190 connected to the equipment shown in FIGS. 1A and 1B and/or described above. The controller 190 can be any type of controller used in an industrial setting, such as a programmable logic controller (PLC). The controller 190 includes a processor 192, a memory 194, and input/output (I/O) circuits 196. The controller 190 can further include one or more of the following components (not shown), such as one or more power supplies, clocks, communication components (e.g., network interface card), and user interfaces typically found in controllers for semiconductor equipment.

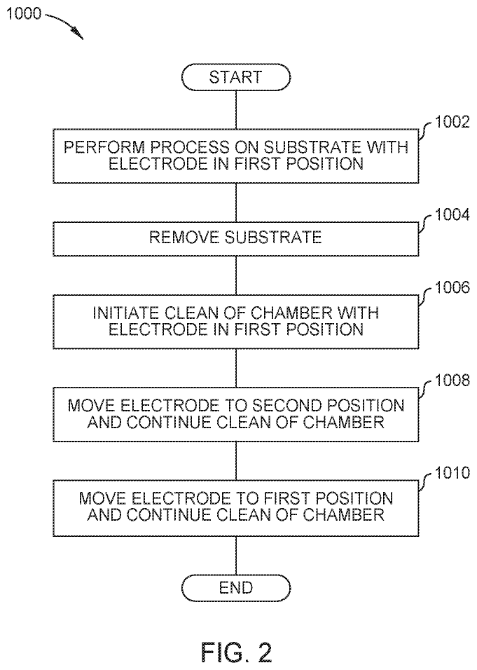

The processor 192 is configured to execute various programs stored in the memory 194, such as a program configured to execute the method described below in reference to FIG. 2. The memory 194 can further include various operational settings used to control the processing system 105. For example, the settings can include settings for controlling (1) the positions of the electrode 151 at different times during a method, (2) the voltage, power, and frequency levels to operate the RF power sources 121, 122 during different portions of a method (3) various process conditions (e.g., temperature, pressure, flowrates of gases, etc.) of the inner volume 106 during different portions of a method among various other settings.

The memory 194 can include non-transitory memory. The non-transitory memory can be used to store routines and settings, such as a routine and settings used to execute the method described below in reference to FIG. 2. The memory 194 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM). Routines for deposition, cleaning, etching, and/or other processes to be performed by the processing system 105 are generally stored in the memory 194. These routines can be executed by the processor 192 with signals being received from inputs (e.g., sensors) and signals being transmitted to outputs (e.g., the actuator 152 or RF power sources 121, 122) through the I/O circuits 196.

FIG. 2 is a process flow diagram of a method 1000 for an exemplary deposition and clean to be performed by the processing chamber 100, according to one embodiment. The following describes exemplary configurations and operating settings for performing a PECVD process in the process chamber 100 for depositing a carbon hardmask layer on the substrate 50 shown in FIG. 1A followed by a subsequent plasma process to clean the processing chamber 100 as shown in FIG. 1B.

At block 1002, the method begins with depositing a carbon hardmask layer on the substrate 50. At block 1002, the electrode 151 is in the first position P1 (FIG. 1A) and the bottom surface 155 of the electrode 151 positioned at a first distance D1 from the top surface 111 of the substrate support 110. The first distance D1 can be from about eight inches to about eighteen inches, such as from about twelve inches to about fourteen inches. This distance is substantially greater than corresponding distances generally used for PECVD processes, which are usually less than one inch.

During the deposition when the electrode 151 is at the first position P1, the first RF power source 121 is energized to provide RF power to the substrate support 110. The RF power provided to the substrate support 110 causes a plasma of process gases supplied from the process gas sources 181 to be created in the inner volume 106. At the first position P1, the electrode 151 is connected to electrical ground. The first RF power source 121 can provide power to the substrate support 110 at a frequency from about 10 MHz to about 121 MHz at a voltage from about 200 V to about 5000 V, such as from about 500 V to about 2000 V. This voltage is higher than voltages typically used for a conventional PECVD process, which are usually less than 100 V. The pressure in the inner volume 106 during the deposition can be from about 1 mTorr to about 500 mTorr. Some exemplary process gases provided to the inner volume 106 during the deposition can include acetylene, methane, and/or propylene. In some embodiments, the process gases can further include hydrogen as well as an inert gas (e.g., helium). In some embodiments, these process gases can be provided to inner volume 106 at a flowrate from about 50 sccm to about 250 sccm. The temperature of the substrate 50 during the deposition can be from about 0 degrees Celsius to about 100 degrees Celsius.

At block 1004, after the deposition is complete, the process gases are no longer supplied to the process chamber 100, the first RF power source 121 is de-energized, and the substrate 50 is removed from the process chamber 100.

At block 1006, the cleaning process can optionally be initiated with the electrode 151 still in the first position P1 or substantially close to the first position P1 (e.g., within 0.5 inches). Cleaning gases from the cleaning gas sources 182 can be supplied to the process chamber 100. The cleaning gases can include one or more of oxygen, argon, and nitrogen. In some embodiments, the oxygen to argon flowrate ration is from about 2:1 to about 10:1, such as about 5:1. In some embodiments, the oxygen flowrate be from about 500 sccm to about 2000 sccm.

At block 1006, the electrode 151 can be disconnected from electrical ground and connected to the second RF power source 122. In some embodiments, this may include moving the electrode 151 at least slightly downward to break the contact with grounding element 166. Once the electrode 151 is disconnected from ground, the second RF power source 122 can begin to provide RF power to the electrode 151. The RF power provided to the electrode 151 causes a plasma of cleaning gases supplied from the cleaning gas sources 182 to be created in the inner volume 106. In some embodiments, the plasma provided at block 1006 can continue for a predetermined amount of time (e.g., one minute or five minutes) before the method 1000 proceeds to the next block.

During block 1006, the second RF power source 122 can provide power to the electrode 151 at a frequency from about 300 kHz to about 60 MHz at a voltage from about 500 V to about 5000 V, such as from about 2000 V to about 2500 V. The pressure in the inner volume 106 during the cleaning can be from about 100 mTorr to about 1 Torr, such as about 300 mTorr.

At block 1008, the electrode 151 is moved by the actuator 152 to the second position P2 (FIG. 1B). If a plasma was initiated at block 1006, the plasma can continue to be generated as the electrode 151 is moved from the first position P1 to the second position P2. In the second position P2, the bottom surface 155 of the electrode 151 is positioned at a second distance D2 from the top surface 111 of the substrate support 110. This second distance D2 can be from about 0.125 inches to about two inches, such as from about 0.5 inches to about one inch. In some embodiments, the first distance D1 (FIG. 1A) can be from about two times greater to about 150 times greater than the second distance D2 (FIG. 1A), for example 18 inches is 144 times greater than 0.125 inches. In other embodiments, the first distance D1 (FIG. 1A) can be from about five times greater to about twenty times greater than the second distance D2 (FIG. 1B), such as about ten times greater.

The differences in these distances (D1 and D2) also generally cause a substantially similar corresponding change to the process volume between the substrate support 110 and the electrode 151. For example, if D1 (FIG. 1A) for a deposition process is ten times greater than D2 (FIG. 1B) for a clean process, then the process volume for the deposition is about ten times greater than the process volume for the clean assuming the horizontal cross-section of the inner volume 106 does not substantially vary in the vertical direction. This ability to change the process volume by a large factor (e.g., ten-fold or more) allows for substantially different processes (e.g., a deposition and clean) to be more effectively performed in a single processing chamber (e.g., processing chamber 100) than would otherwise be possible without a feature to change the processing volume like the movable electrode 151.

At the second position P2, the second RF power source 122 can provide power to the electrode 151 at a frequency from about 300 kHz to about 60 MHz at a voltage from about 500 V to about 5000 V, such as from about 2000 V to about 2500 V. After reaching the second position P2, the second RF power source 122 can provide RF power to the electrode 151 to maintain the plasma for a predetermined time period, such as for one minute or five minutes.

The pressure in the inner volume 106 during the cleaning at block 1008 can be from about 10 mTorr to about 5 Torr. The pressure of the inner volume 106 at block 1006 before the electrode 151 is moved can often be lower than the pressure at block 1008. This pressure can be increased as the electrode 151 moves towards the substrate support 110 or when the electrode reaches the second position P2. The increased pressure can create a higher plasma density, which can enable more effective cleaning.

At block 1010, the electrode 151 is moved by the actuator 152 back to the first position P1 (FIG. 1A). The cleaning process executed at block 1008 can optionally continue maintaining the cleaning plasma as the electrode 151 is moved from the second position P2 to the first position P1. The cleaning plasma can also optionally continue for a predetermined time period after the electrode 151 arrives at the first position P1, such as for one minute or five minutes.

In some embodiments, the first RF power source 121 also provides RF power to the substrate support during the cleaning of the process chamber 100, for example during one or more of blocks 1006-1010. However, in some embodiments, the substrate support can remain grounded during one or more of blocks 1006-1010.

The processing chamber 100 described above with the movable electrode 151 allows processes to be completed in substantially different process volumes. For example, the process volume of the deposition described in reference to FIG. 1A can be greater than the process volume of the cleaning process described in reference to FIG. 1B by a factor of ten or more. These substantially different process volumes allow substantially different processes to be completed in a single processing chamber. Furthermore, the ability to change the process volume allows for the process volume for a substrate process (e.g., a deposition) to be independent of the process volume of a subsequent cleaning process in the process chamber. Better results for depositing carbon hardmask layers have been obtained in the larger process volumes described in reference to FIG. 1A, but this same process volume makes cleaning the interior of the processing chamber substantially less effective than a corresponding clean performed at the reduced process volume described in reference to FIG. 1B. Thus, the movable electrode 151 that is connected to the bellows 161 and surrounded by the plasma screen 165 allows for the process volume to be changed, so that a successful and efficient plasma deposition (FIG. 1A) and plasma clean (FIG. 1B) can be performed in the same processing chamber. Furthermore, the electrode 151 only has a single electrical connection to the second RF power source 122 and is spaced apart from any gas connections or other moving parts, which makes adjusting the process volume of the processing chamber with the electrode 151 substantially less complex than attempting to adjust the process volume, for example, by moving the substrate support, which often has fluid connections (e.g., backside gas), moving parts (e.g., lift pins), as well as multiple electrical connections (e.g., electrostatic chuck power, RF power, lift pin power, and electrical for any sensors).

While the foregoing is directed to embodiments of the present disclosure, other and further embodiments of the disclosure may be devised without departing from the basic scope thereof, and the scope thereof is determined by the claims that follow.

1. A process chamber, comprising:
a chamber body enclosing an inner volume;
a substrate support disposed in the inner volume;
an electrode disposed above the substrate support; and
an actuator configured to move the electrode in the process chamber to change a distance between the electrode and the substrate support.

2. The process chamber of claim 1, wherein
the actuator is configured to be move the electrode from a first position located a first distance from the substrate support to a second position located a second distance from the substrate support, and
the first distance is at least five times greater than the second distance.

3. The process chamber of claim 2, wherein the electrode is electrically connected to the chamber body at the first position and electrically isolated from the chamber body at the second position.

4. The process chamber of claim 1, wherein
the actuator is configured to move the electrode from a first position located a first distance from the substrate support to a second position located a second distance from the substrate support,
the first distance is from about eight inches to about eighteen inches, and
the second distance is from about 0.125 inches to about 2.0 inches.

5. The process chamber of claim 1, further comprising a bellows, wherein the chamber body comprises a lid disposed above the electrode and the bellows is disposed between the electrode and the lid.

6. The process chamber of claim 5, wherein the bellows is connected to the electrode and the bellows is configured to extend or contract when the electrode is moved by the actuator.

7. The process chamber of claim 1, further comprising a plasma screen disposed around the electrode.

8. The process chamber of claim 7, wherein the plasma screen is configured to move when the electrode is moved by the actuator.

9. A method of performing a process in a process chamber, the method comprising:
providing RF power to a substrate support disposed in an inner volume of a process chamber to initiate a first plasma in the inner volume to perform a process on a substrate disposed on the substrate support, wherein the process chamber includes an electrode disposed above the substrate support and the electrode is located at a first position during the first plasma;
moving the electrode vertically from the first position to a second position; and
providing RF power to the electrode located in the second position to initiate a second plasma in the inner volume.

10. The method of claim 9, wherein
the electrode is located a first distance from the substrate support at the first position,
the electrode is located a second distance from the substrate support at the second position, and
the first distance is at least five times greater than the second distance.

11. The method of claim 10, wherein the electrode is electrically connected to a chamber body of the process chamber at the first position and electrically isolated from the chamber body at the second position.

12. The method of claim 9, wherein the second plasma is a plasma of cleaning gases configured to clean an interior of the process chamber.

13. The method of claim 9, further comprising:
supplying one or more cleaning gases to the inner volume as the electrode is moved from the first position to the second position; and
providing RF power to the electrode as the electrode is moved from the first position to the second position to create a plasma of the cleaning gases as the electrode is moved from the first position to the second position.

14. The method of claim 9, further comprising:
moving the electrode from the second position back to the first position;
supplying one or more cleaning gases to the inner volume as the electrode is moved from the first position to the second position; and
providing RF power to the electrode as the electrode is moved from the second position back to the first position to create a plasma of the cleaning gases as the electrode is moved from the second position back to the second position.

15. The method of claim 9, wherein the first plasma is initiated with a first RF power source and the second plasma is initiated with a second RF power source.

16. The method of claim 9, wherein moving the electrode vertically from the first position to the second position comprises vertically moving the electrode at least eight inches.

17. The method of claim 9, wherein moving the electrode vertically from the first position to the second position causes a bellows connected to the electrode to extend in a vertical direction.

18. The method of claim 17, wherein a plasma screen surrounds the electrode as the electrode is moved from the first position to the second position.

19. A process chamber, comprising:
a chamber body enclosing an inner volume;
a substrate support disposed in the inner volume;
an electrode disposed above the substrate support;
an actuator configured to move the electrode in the process chamber to vertically change a distance between the electrode and the substrate support by at least eight inches; and
a bellows, wherein the chamber body comprises a lid disposed above the electrode and the bellows is disposed between the electrode and the lid.

20. The process chamber of claim 19, further comprising a plasma screen disposed around the electrode, wherein
the plasma screen is configured to move when the electrode is moved by the actuator, and
the bellows is connected to the electrode and the bellows is configured to extend or contract when the electrode is moved by the actuator.
